(19) United States
(12) Patent Application Publication
(10) Pub. No.: US 2016/0111400 A1
(43) Pub. Date: Apr. 21, 2016

(54) LIGHT EMITTING DEVICE

(71) Applicant: ADVANCED OPTOELECTRONIC TECHNOLOGY, INC., Hsinchu Hsien (TW)

(72) Inventors: HOU-TE LIN, Hukou (TW); CHAO-HSIUNG CHANG, Hukou (TW); PIN-CHUAN CHEN, Hukou (TW); LUNG-HSIN CHEN, Hukou (TW); WEN-LIANG TSENG, Hukou (TW)

(21) Appl. No.: 14/832,725

(22) Filed: Aug. 21, 2015

(30) Foreign Application Priority Data
Oct. 20, 2014 (CN) 201410556311.6

(51) Int. Cl. H01L 25/075; H01L 33/38; H01L 33/50; H01L 33/62; H01L 33/54

(52) U.S. Cl. CPC H01L 25/0753; H01L 33/62; H01L 33/54; H01L 33/507; H01L 33/38

(57) ABSTRACT

A flip chip light emitting diode includes a plurality of light emitting diodes and an encapsulation covering the plurality of light emitting diodes. Each of light emitting diode has a P electrode and an N electrode which are exposed out of the encapsulation.

### CROSS-REFERENCE TO RELATED APPLICATIONS

This application claims priority to Chinese Patent Application No. 201410556311.6 filed on Oct. 20, 2014, the contents of which are incorporated by reference herein.

### FIELD

The subject matter herein generally relates to a light emitting device, especially relates to a light emitting diode packaging coupled with a circuit.

### BACKGROUND

A generally light emitting diode packaging includes a base plate and a light emitting diode mounted on the base plate. The light emitting diode packaging is coupled to a circuit by the base plate. According to different demands of brightness and scope of the light, a plurality of grooves is generally formed on the light emitting diode packaging to cooperate with the circuit.

### BRIEF DESCRIPTION OF THE DRAWINGS

Implementations of the present technology will now be described, by way of example only, with reference to the attached figures.

FIG. 1 is a diagrammatic view of a light emitting device of a first embodiment of the present disclosure.

FIG. 2 is a bottom view of the light emitting diode packaging of FIG. 1.

FIG. 3 is a cross sectional view of the light emitting diode of FIG. 1.

FIG. 4 is a bottom diagrammatic view of a light emitting device of a second embodiment of the present disclosure.

### DETAILED DESCRIPTION OF EMBODIMENTS

It will be appreciated that for simplicity and clarity of illustration, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure. The description is not to be considered as limiting the scope of the embodiments described herein.

Several definitions that apply throughout this disclosure will now be presented. The term “comprising” means “including, but not necessarily limited to”; it specifically indicates open-ended inclusion or membership in a so-described combination, group, series and the like. The term “coupled” is defined as connected, whether directly or indirectly through intervening components, and is not necessarily limited to physical connections. The connection can be such that the objects are permanently connected or releasably connected.

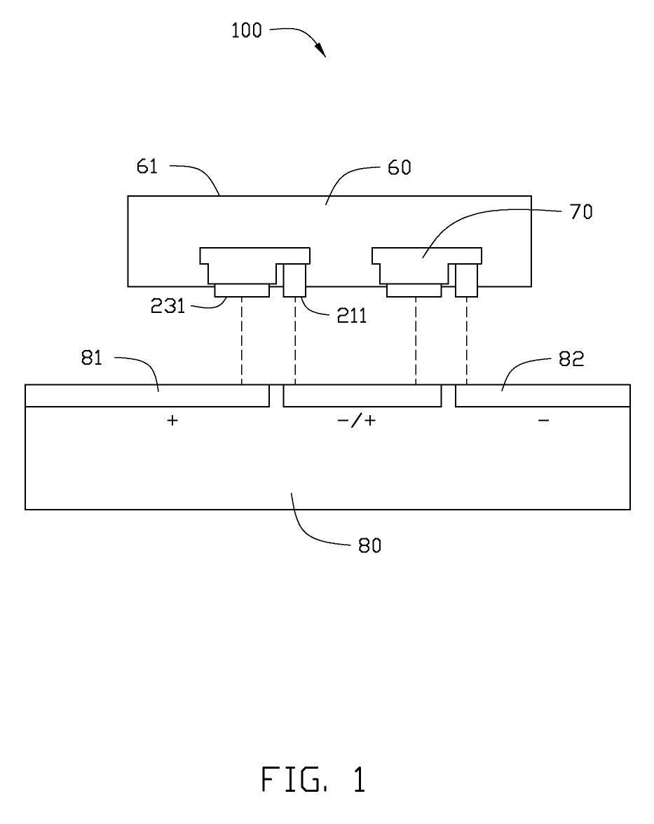

As illustrated in FIG. 1, a light emitting device includes a light emitting diode packaging 100 and a circuit 80 coupled with the light emitting diode packaging 100. The light emitting diode packaging 100 includes an encapsulation layer 60 and a plurality of light emitting diodes 70 covered by the encapsulation layer 60. The light emitting diode packaging 100 has a light emitting surface 61 on top of the encapsulation layer 60.

The encapsulation layer 60 is made of transparent material. The encapsulation layer 60 can further include phosphors therein. Each light emitting diode 70 is embedded from bottom of the encapsulation layer 60. The light emitting diodes 70 are packaged together by the encapsulation layer 60 to form a single component.

In the illustrated embodiment, the circuit 80 is a series circuit and has a positive electrode 81 and a negative electrode 82. The positive electrode 81 and the negative 82 are multiple mounted on the circuit 80.

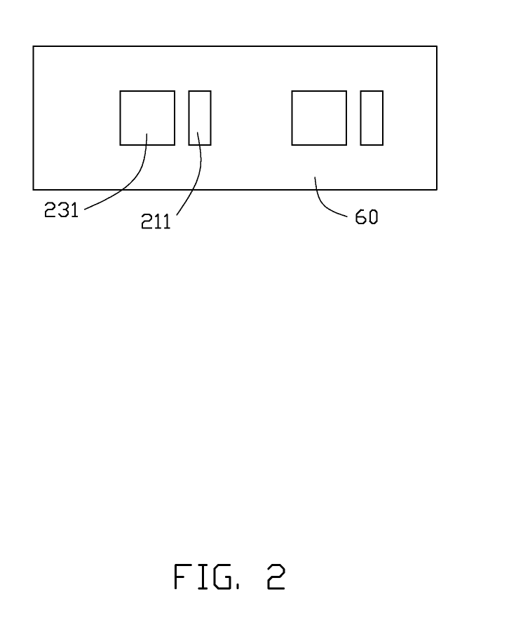

Also as illustrated in FIG. 2, each light emitting diode 70 has a P electrode 231 and an N electrode 211 thereon. The P electrodes 231 and the N electrodes 211 are located opposite to the light exiting surface 61 of the light emitting diode packaging 100, and are exposed out of the encapsulation layer 60. The P electrode 231 and the N electrode 211 of each light emitting diode 70 couple with the circuit 80. Each P electrode 231 is corresponding to the positive electrode 81, and each N electrode is corresponding to a negative electrode 82.

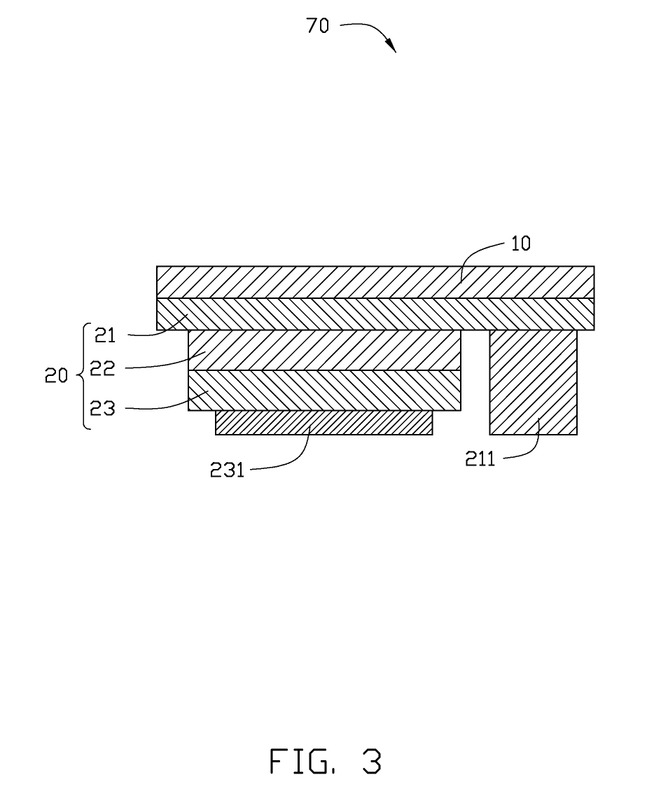

As illustrated in FIG. 3, the light emitting diodes 70 are coupled with the circuit 80 by flip chip bonding. A high power light emitting diode packaging can be formed from a plurality of light emitting diode 70. In this embodiment, the light emitting diode packaging 100 includes two light emitting diodes 70. Each light emitting diode 70 includes a substrate 10 and a semiconductor layer 20 formed on the substrate 10. The substrate 10 is made of sapphire. The semiconductor layer 20 includes an N semiconductor layer 21, a light emitting layer 22 and a P semiconductor layer 23 arranged in series. The P electrode 231 is mounted on the P semiconductor layer 23, and the N electrode 211 is mounted on the N semiconductor layer 21. The N semiconductor layer 21 and the P semiconductor layer 23 are made of Gallium nitride. The N semiconductor layer 21 provides holes, and the P semiconductor layer 23 provides electrons. The light emitting layer 22 gathers the holes and the electrons together to emit light.

In the illustrated embodiment, the P electrode 231 and the N electrode 211 of the light emitting diode 70 are exposed out of the encapsulation layer 60, so that the light emitting diode packaging 100 is coupled with the circuit 80 directly by the P electrodes 231 coupled to the positive electrode 81 and the N electrodes 211 coupled to the negative electrode 82. While the circuit 80 has a structure that is changed, the P electrode 231 and the N electrode 211 of the light emitting diode packaging 100 are coupled with the circuit 80 by changing the connecting method, the structure of the light emitting diode packaging 100 need not be changed. Also, the number of the light emitting diodes 70 can be changed to couple with the circuit 80 to satisfy the different demands of the luminous power. Thus, the light emitting diode packaging 100 has a great applicability to couple with the circuit 80.

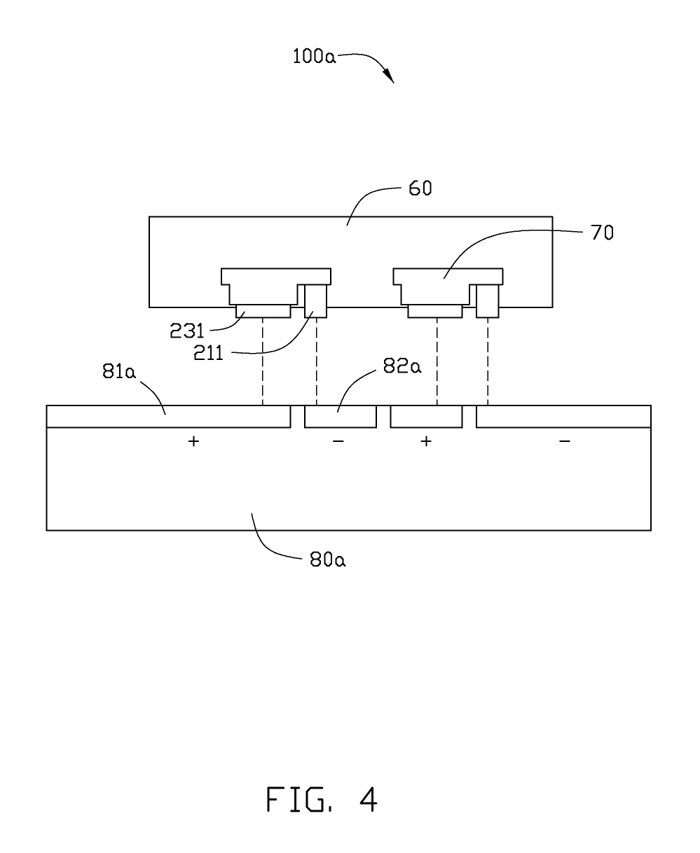

As illustrated in FIG. 4, the light emitting device includes the light emitting diode packaging 100a and a circuit 80a is coupled to the light emitting diode packaging 100a. The circuit 80a has a parallel circuit and includes a positive electrode 81a and a negative electrode 82a. The positive 81a and the negative electrode 82a are multiple.

Each positive 81a is coupled to a corresponding P electrode 231, and each negative 82a is coupled to a corresponding N electrode 211.

The embodiments shown and described above are only examples. Many details are often found in the art such as the other features of light emitting device. Therefore, many such details are neither shown nor described. Even though numerous characteristics and advantages of the present technology have been set forth in the foregoing description, together with details of the structure and function of the present disclosure, the disclosure is illustrative only, and changes can be made in the detail, including in matters of shape, size and arrangement of the parts within the principles of the present disclosure up to, and including the full extent established by the broad general meaning of the terms used in the claims. It will therefore be appreciated that the embodiments described above can be modified within the scope of the claims.

What is claimed is:

1. A light emitting diode packaging configured to be coupled to a circuit, the light emitting diode packaging comprising:
a light emitting diode having a P electrode, an N electrode and a light exiting surface opposite to the P electrode and the N electrode;
an encapsulation layer covering the light emitting diode, while leaving the P electrode and N electrode at least partially exposed from the encapsulation layer; and
wherein the P electrode and the N electrode is configured to be coupled to the circuit.

2. The light emitting diode packaging of claim 1, wherein the light emitting diode is coupled with the circuit by flip chip bonding.

3. The light emitting diode packaging of claim 2, wherein the number of the light emitting diode is multiple.

4. The light emitting diode packaging of claim 3, wherein the light emitting diodes are packaged together by the encapsulation layer to form a single component.

5. The light emitting diode packaging of claim 2, wherein the light emitting diode comprises a substrate and a semiconductor layer formed on the substrate.

6. The light emitting diode packaging of claim 5, wherein the semiconductor layer comprises an N semiconductor, a light emitting layer, and a P semiconductor layer arranged in serious on the substrate.

7. The light emitting diode packaging of claim 1, wherein the encapsulation layer is made of transparent resin.

8. The light emitting diode packaging of claim 1, wherein the encapsulation layer comprises phosphors.

9. A light emitting device, comprising:
a light emitting diode packaging comprising:
a plurality of light emitting diodes, each light emitting diode having a P electrode and an N electrode thereon and a light exiting surface opposite to the P electrode and N electrode;
an encapsulation layer covering the light emitting diodes with the P electrodes and N electrodes exposed out of the encapsulation layer; and
a circuit including a plurality of positive electrodes coupled with the corresponding P electrodes and a plurality of negative electrodes coupled with the corresponding N electrodes.

10. The light emitting device of claim 9, wherein the light emitting diodes are coupled with the circuit by flip chip bonding.

11. The light emitting device of claim 9, wherein the encapsulation layer comprises phosphors.

12. The light emitting device of claim 9, wherein the circuit includes parallel circuit and series circuit.
